(19) United States
(12) Patent Application Publication
(10) Pub. No.: US 2018/0144910 A1
(43) Pub. Date: May 24, 2018

(54) METHOD FOR TREATING THE SURFACE OF A MOVING FILM, AND FACILITY FOR IMPLEMENTING SAID METHOD

(71) Applicant: COATING PLASMA INDUSTRIE, Peynier (FR)

(72) Inventor: Eric GAT, Peynier (FR)

(73) Assignee: COATING PLASMA INDUSTRIE, Peynier (FR)

(21) Appl. No.: 15/564,017

(22) PCT Filed: Apr. 7, 2016
(86) PCT No.: PCT/FR2016/050792

§ 371 Date: Oct. 3, 2017

(30) Foreign Application Priority Data
Apr. 20, 2015 (FR) 1553503

(51) Int. Cl. H01J 37/32; C23C 16/54; C23C 16/455

(52) U.S. Cl. CPC H01J 37/32825; C23C 16/45595; C23C 16/545; H01J 37/32449

(57) ABSTRACT

A method carried out in a facility having an enclosure, a support for the substrate, a counter-electrode, a head provided with an electrode, a device for diffusing an inert gas and device for injecting an active gas mixture towards the support. The method involves continuously introducing bath the inert gas and the active gas mixture towards the support, continuously activating the reactive gas in the electrical discharge and treating the surface of the moving substrate, continuously discharging, via the outlet, the gaseous atmosphere from the inner volume comprising a fraction of the inert gas and the active gas mixture, adjusting the effective cross-section of the outlet and/or adjusting the total flow rate of the inert gas and the active gas mixture, such that the inner volume of each head is at a slight overpressure relative to the inner volume of the enclosure.

### TECHNICAL FIELD OF THE INVENTION

The invention relates to a method for treating a surface of a moving substrate. More specifically, it is aimed at a method in which the substrate is subjected to a plasma generated in a gaseous mixture, which leads to the modification of the surface state of this substrate and/or to the formation of a deposit on the aforementioned surface. The invention relates in particular to such a method, which can be implemented at a pressure close to atmospheric pressure, and which is suitable for the continuous surface treatment of polymer films in rolls (“roll-to-roll” method).

### PRIOR ART

Methods, aiming to modify and improve the surface properties of a substrate via a plasma, are already known. Such properties of interest can be, for example, the surface energy or the adhesion properties of this substrate. The substrates at which the invention is aimed can be in particular insulators such as polymer films, or metal films.

According to these known methods, for the deposition of a thin solid layer onto the surface of a substrate, this surface is subjected to a plasma created by an electrical discharge in a gas and, simultaneously or afterwards, the substrate thus treated is exposed to a gaseous mixture that contains an active gaseous compound, which is suitable for inducing the deposition of this thin solid film.

Continuously implementing methods for treating a substrate via an electrical discharge in a gaseous mixture, wherein the substrate is moved at speeds between approximately ten and several hundreds of meters per minute, typically in a chamber, is also known. Said chamber contains, besides the electrodes necessary for the creation of the discharge, a device for injecting the active gaseous mixture, as well as means for evacuating the gaseous effluents.

U.S. Pat. No. 8,851,012 describes a method for treating the surface of a substrate, using a head provided with a first electrode, as well as with a central channel allowing a polymer or a carrier gas to be supplied, via auxiliary channels. This document teaches certain size ranges, in particular with regard to the distance between the substrate and the members for injecting the various gaseous compounds. This document provides spatial separation between the injection of a carrier gas and the diffusion of a plasma-generating gas.

The object of EP-A-2 762 609 is a method for treating a surface of a moving substrate, wherein an inert gas and an active gaseous mixture are introduced towards a support, then the reactant gas is activated and the surface of the aforementioned substrate is treated. The gaseous atmosphere, which comprises a fraction of the inert gas and of the active gaseous mixture, is then evacuated.

US 2003/113479 discloses an apparatus for treatment by plasma, comprising two opposite electrodes defining a discharge space, as well as means for providing a reactant gas and an inert gas to this discharge space. The reactant gas is excited in this discharge space via application of a voltage, but is not placed in direct contact with the discharge surface of the two aforementioned electrodes.

FR 2 816 726 A describes a method of the above type, which is implemented via a facility comprising a chamber for receiving the electrodes. This facility is further provided with auxiliary units, allowing the entry of air into the chamber, as well as the outlet of the gaseous mixture out of this chamber, respectively, to be prevented. Each auxiliary unit comprises a slot for injecting nitrogen allowing the creation, when on, of gaseous “knives”. Means are further provided in order to adjust the gaseous flow rates, in such a way as to maintain a difference in pressure between the inside of the chamber and the outside atmosphere close to zero.

However, the method described in FR-A-2 816 726 involves certain disadvantages. First of all, it uses gaseous knives that involve a high consumption of nitrogen. Moreover, the control of the conditions inside the chamber is relatively complex to implement. In particular, the pressure inside the chamber is difficult to regulate in a stable and reproducible manner. In other words, this pressure is subject to noticeable variations, which are not favorable to good control of this method. Finally, the facility described in FR-A-2 816 726, which allows this method to be implemented, is relatively complicated and costly.

Given the above, one goal of the present invention is to at least partially overcome the disadvantages of the prior art mentioned above.

Another goal of the invention is to propose a method that, while providing reliable surface treatment of a substrate, in particular “roll-to-roll” treatment, at a pressure close to atmospheric pressure, allows the quantity of inert gas consumed to be significantly reduced, with respect to the prior art.

Another goal of the invention is to propose such a method, which is easy to control and which can be implemented using a relatively simple facility.

### OBJECT OF THE INVENTION

According to the invention, the above goals are reached via a method for treating a surface of a moving substrate, in a facility comprising
a chamber;
a support for the substrate, received in said chamber;
a counter electrode;
   at least one head defining an inner volume open towards the support, said head being provided
   with at least one electrode suitable for cooperating with said counter electrode in order to create an electrical discharge;
   diffusion means for the diffusion of an inert gas towards said support; and
   injection means, distinct from the diffusion means, for the injection of at least one active gaseous mixture towards said support, this active gaseous mixture comprising a reactant gas suitable for being activated by said electrical discharge;
   the injection means being placed between the diffusion means and the support;
the head and the support defining at least one outlet for the inert gas and/or the active gaseous mixture,

wherein in this method

i. both the inert gas and the active gaseous mixture are introduced towards said support, in such a way as to press the active gaseous mixture against said support;

ii. the reactant gas is activated in said electrical discharge and the surface of said moving substrate is treated;

iii. via said outlet, the gaseous atmosphere of the inner volume (V) is evacuated, said gaseous atmosphere comprising a fraction of the inert gas and of the active gaseous mixture;

iv. the effective cross-section of the outlet is adjusted and/or the total flow rate of the inert gas and of the active gaseous mixture is adjusted, in such a way that the difference in pressure (P1−P0; P2−P0) between the inner volume of each head and the inner volume of the chamber is greater than 10 Pascal,

with steps (i) to (iv) not necessarily being chronological.

The method according to the invention allows the need to use intake and outlet units associated with nitrogen knives, as known from FR-A-2 816 726, to be eliminated. Consequently, this method allows a substantial reduction in the consumption of inert gas, with respect to this prior art. The overall structure of the facility, which allows the implementation of the method of the invention, is clearly simplified as a result.

Moreover, the applicant has discovered that surprisingly, injecting the active gaseous mixture near the substrate, while diffusing the inert gas from the inside of the chamber, provides plasma treatment of satisfactory quality. Indeed, this allows any substantial leak of this active gaseous mixture out of the chamber to be prevented. In other words, substantially the totality of the reactant gas is deposited on the surfaces exposed to the plasma.

Without wanting to be bound by this theory, the inventors think that this could be due to the fact that the gaseous mixture is pushed, or pressed, against the substrate, under the effect of the inert gas. The latter moreover prevents all significant entry, into the zone of discharge defined by the electrodes, of air, possibly loaded with impurities such as dust, carried by the moving substrate.

This effect of pressing of the gaseous mixture, by the inert gas, is also produced by the slight overpressurization of the head with respect to the rest of the chamber. The difference in pressure between the inner volumes of this head and of this chamber is typically greater than 10 Pascal (Pa). Advantageously, this difference is greater than 20 Pascal, namely 50 Pascal.

It should also be noted that the present invention is advantageous in terms of safety and flexibility, with respect to the solution described in FR-A-2 816 726. Indeed, in this prior solution, the treatment chamber cannot be placed at a high overpressure value, in order to prevent any significant leak of nitrogen into the ambient atmosphere. Thus, there is a risk of this overpressure being slight, or even of there being an inversion of pressures that can lead to an undesired arrival of oxygen in the chamber.

The value of the overpressure, used in the present invention, can first of all be modified by adjusting the effective cross-section of the outlet. This is typically obtained by acting on the position of the head with respect to the support. In this case, if the head is moved away from the support, this tends to reduce the value of this overpressure, while if the head is moved closer, the value of this overpressure is increased.

In addition or alternatively, action can also be taken on the value of the overall gaseous flow rate, which consists of the sum of the respective flow rates of the inert gas and of the active gaseous mixture. In this case, if this overall flow rate is increased, this tends to increase the value of this overpressure. However, a reduction in this overall flow rate is accompanied by a reduction in this overpressure value.

According to other features of the invention:

(a) the effective cross-section of the outlet is adjusted and/or the total flow rate of the inert gas and of the active gaseous mixture is adjusted, in such a way that the difference in pressure between the inner volume of each head and the inner volume of the chamber is greater than 20 Pascal, in particular greater than 50 Pascal;

(b) the inert gas is injected at a flow rate between 1 and 10 liters per square meter, namely between 2.5 and 5 liters per square meter;

(c) the active gaseous mixture is injected at a flow rate between 1 and 100 milliliters per square meter, namely between 5 and 50 milliliters per square meter;

(d) the ratio between the flow rate of the inert gas and the flow rate of the active gaseous mixture is between 100 and 10,000, namely between 500 and 5,000;

(e) the head is positioned with respect to the support, in such a way that the height of the outlet is between 0.5 and 2.5 millimeters, namely between 0.8 and 1.2 millimeters;

(f) the inert gas is injected at at least one point of injection of inert gas, the distance between each point of injection of inert gas and the support being between 50 and 150 millimeters, namely between 75 and 125 millimeters;

(g) the active gaseous mixture is injected at at least one point of injection of gaseous mixture, the distance between each point of injection of gaseous mixture and the support being between 0.5 and 3.0 millimeters, namely between 1.0 and 1.5 millimeters;

(h) the oxygen concentration in the inner volume of each head is measured and the effective cross-section of the outlet is adjusted and/or the total flow rate of the inert gas and of the active gaseous mixture is adjusted, if this measured concentration is outside of a predetermined range;

(i) the active gaseous mixture comprises, besides the reactant gas, a carrier gas;

(j) an inert gas of a first type, namely nitrogen, and a carrier gas of a different type, namely helium, are used;

(j′) a carrier gas that has improved plasma-generating properties with respect to nitrogen, such as a noble gas such as helium or argon, is chosen.

(k) the reactant gas comprises at least one monomer and/or at least one dopant;

(l) a first active gaseous mixture comprising hydrogen as the reactant gas is injected, into at least one upstream injection member, in order to eliminate at least a portion of the oxygen boundary layer present on the surface of the substrate, then a second active gaseous mixture different than the first active gaseous mixture is injected, into at least one downstream injection member, at the surface of the substrate freed from at least a portion of said layer of oxygen;

(m) the or each upstream injection member is provided in an additional upstream chamber, distinct from the chamber, whereas the or each downstream injection member is provided in the chamber;

(n) the or each upstream injection member is provided in a first head, or upstream head, of the chamber, whereas the or each downstream injection member is provided in a second head, or downstream head, of the chamber;

(o) the or each upstream injection member, thus the or each downstream injection member, are provided in a single head;

(p) the substrate passes into an auxiliary chamber placed upstream of the chamber, and this substrate is pressed via at least one roller received in this auxiliary chamber, in order to at least partially eliminate the layer of air present on the surface of the substrate;

(q) the inner volume of this auxiliary chamber is placed under vacuum.

These additional features (a) to (q) can be implemented individually or in various combinations.

The above goals are also reached via a facility for the implementation of a method as above, comprising:
a chamber;
a support for the substrate, received in said chamber;
a counter electrode;
   at least one head defining an inner volume open towards the support, said head being provided
   with at least one electrode suitable for cooperating with said counter electrode in order to create an electrical discharge;
   diffusion means for the diffusion of an inert gas towards said support; and
   injection means, distinct from the diffusion means, for the injection of at least one active gaseous mixture towards said support, this active gaseous mixture comprising a reactant gas suitable for being activated by said electrical discharge;
   the injection means being placed between the diffusion means and the support
the head and the support defining at least one outlet for the inert gas and/or the active gaseous mixture,

this facility further comprising means for adjusting the effective cross-section of the outlet and/or means for adjusting the total flow rate of the inert gas and of the active gaseous mixture.

According to an advantageous feature, the facility further comprises an auxiliary chamber, placed upstream of the chamber, said auxiliary chamber being provided with at least one press roller suitable for at least partially eliminating the layer of air present on the surface of the substrate.

### DESCRIPTION OF THE DRAWINGS

The invention will be described below, in reference to the appended drawings, given only as non-limiting examples, in which:

FIG. 1 is a front view, illustrating a facility allowing the implementation of a method for surface treatment according to the invention.

FIG. 2 is a perspective view, illustrating a chamber belonging to the facility of FIG. 1.

FIG. 3 is a perspective view, illustrating, on a larger scale, a head belonging to the facility of FIG. 1, the front wall of this head being omitted.

FIG. 4 is a front view illustrating the head of FIG. 3.

FIG. 5 is a front view illustrating a tube that belongs to the head of FIG. 3.

FIGS. 6 and 7 are views on a larger scale, illustrating the details VI and VII in FIG. 5.

FIG. 8 is a front view, illustrating, on an even larger scale, two electrodes and a tube that belong to the head of FIG. 3.

FIG. 9 is a front view, illustrating a facility allowing the implementation of an alternative embodiment of the method according to the invention.

FIGS. 10 and 11 are schematic front views, analogous to FIG. 9, illustrating two alternatives for the implementation of the method according to the invention.

FIG. 12 is a front view, analogous to FIG. 9, illustrating a facility allowing the implementation of an additional alternative embodiment of the method according to the invention.

The following numerical references are used in the present description:

| | |
|---|---|
| 7, 7′, 7″ Tubes | 130 Width of 30 |
| L7 Length of 7 | V Inner volume of 30 |
| D7 Diameter of 7 | E Intake |
| R7 Direction of rotation of 7 | S Outlet |
| d7 Distance between 7 and S | 40 Upper portion of 30 |
| 8, 8′, 8″ Electrodes | 42 Diffusers |
| L8 Length of 8 | 50 Lower portion of 30 |
| 18 Width of 8 | 60 Filter |
| d8 Distance between 8 and S | 71 Orifices of 7 |
| 10 Chamber | 72 Orifices of 7 |
| 110 Width of 10 | L71 Length of 71 |
| L10 Length of 10 | 76 Flange |
| 11 Upper wall of 10 | 78 Yoke |
| 12 Front wall of 10 | d78 Distance between 7 |
| | and 8 |
| 13 Rear wall of 10 | 90 Source of nitrogen |
| 14 Lateral wall of 10 | 91 Upstream line |
| 15 Lateral wall of 10 | 92 Downstream line |
| 16 Rails | 94 Sensor |
| 17 Duct | 96 Controller |
| 18 Window | 97 Line |
| 19 Door | 98 Line |
| 20 Drum | 110 Chamber |
| R20 Rotation of 20 | 116, 116′, 116″ Rails |
| SUB Substrate | 130₁ to 130ₙ Heads |
| 22 Nip | 210 Chamber |
| 30 Head | 221 Preliminary chamber |
| 31 Cover | E210 Intake of 210 |
| 32 Front wall of 30 | S210 Outlet of 210 |
| 33 Rear wall of 30 | E221 Intake of 221 |
| 34 Lateral wall of 30 | 222, 222′ Rollers |
| 35 Lateral wall of 30 | 224 Suction device |
| L30 Length of 30 | |

### DETAILED DESCRIPTION

The facility of the invention comprises, first of all, a body or chamber 10, which has an upper wall 11 and peripheral walls, formed by parallel front 12 and rear 13 walls, as well as parallel lateral walls 14 and 15. For example, its length L10, namely the distance between the walls 12 and 13, is between 1,000 mm and 2,000 mm. For example, its width 110, namely the distance between the walls 14 and 15, is between 1,000 mm and 2,000 mm. The chamber is also provided with a duct 17, of a type known per se, in order to suck up an excess of gas outside of the inner volume of the chamber 10.

As is shown schematically in FIG. 2, which illustrates only the chamber from the rear, rails 16 extend between the walls 12 and 13. They are fastened onto these walls, via any suitable means. The function of these rails will be described below. A window 18 and a door 19 are provided on the rear wall 13, in order to allow access to the rails 16.

The facility further comprises a drum 20 that is rotated, when on, in the direction represented by the arrow R20. This drum forms a support for the substrate SUB intended to be treated according to the invention. In the present embodiment, this drum carries out an additional function of counter electrode, which cooperates with electrodes that will be described below. However, this counter electrode can be formed by another component of the facility. For example, the substrate is made of polypropylene, while its thickness is between 20 and 100 micrometers.

In its upstream portion, with respect to the movement of the substrate, the drum is associated with a press roller 22 (also called a “nip” by a person skilled in the art), of a type known per se. This secondary roller 22 allows the substrate to be pressed against the drum 20, in such a way as to prevent the formation of a layer of air between this substrate and this drum. This allows any local treatment defect on the substrate to be prevented.

Above the drum 20, a head 30 is provided, said head being provided with tubes and electrodes, as will be explained below. The width 130 of the head 30 is clearly less than the width 110 of the chamber. This head extends along an arc of a circle defined by the drum 20, in an approximately central manner.

The length L30 of this head is for example slightly less than the length L10, in particular if the substrate substantially covers the entire length of the drum. However, if this substrate only covers a portion of this drum, the length L30 of this head can be clearly less than L10, in such a way that the head does not protrude longitudinally beyond the substrate.

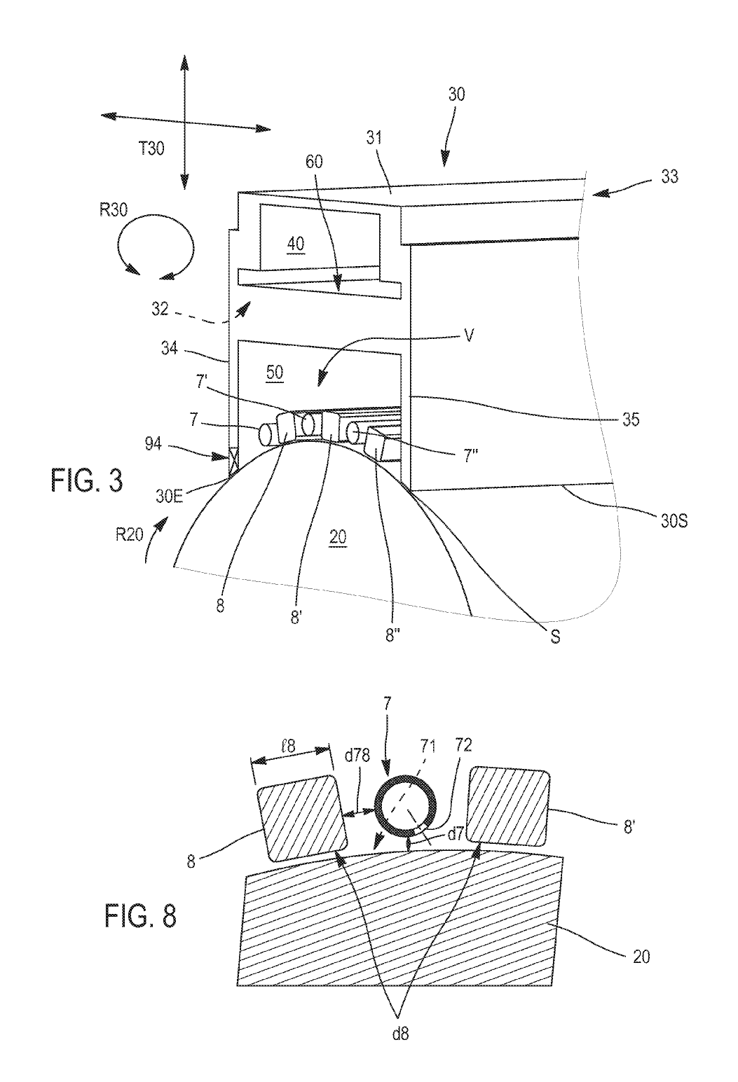

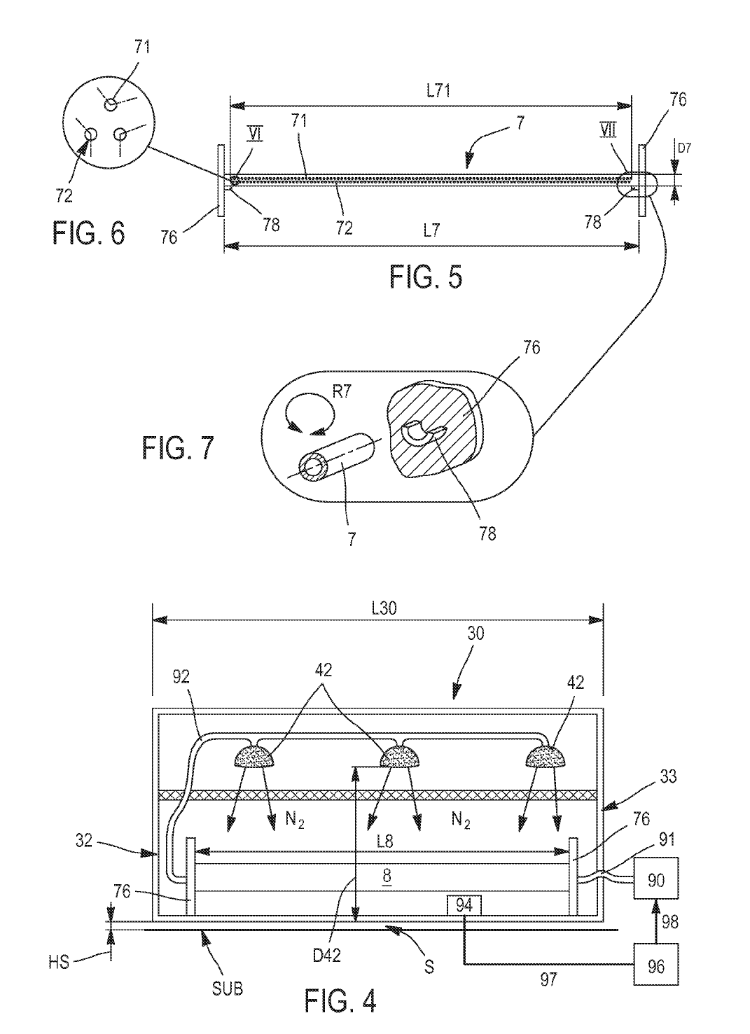

In reference to FIGS. 3 and 4, the head 30 comprises a cover 31 and peripheral walls, formed by parallel front and rear walls 32 and 33, as well as by lateral walls 34 and 35. For example, it is made of PET (polyethylene terephthalate). For reasons of clarity, the front wall 32 is omitted in FIG. 3, whereas it is shown in FIG. 4.

The upper portions of the lateral walls cooperate with the rails 16, for the attachment of the head. Preferably, this attachment allows the head 30 to be mounted onto the rails 16 removably, in particular by snapping on.

This head 30 defines an inner volume V that is open towards the drum 20. The latter defines, with each free edge 30E and 30S of the head, two spaces E and S forming an intake E and an outlet S, respectively. The intake E corresponds to the upstream side, through which the substrate enters, whereas the outlet S corresponds to the downstream side. As will be described in more detail below, this outlet carries out the continuous evacuation of the gaseous atmosphere initially present in the volume V.

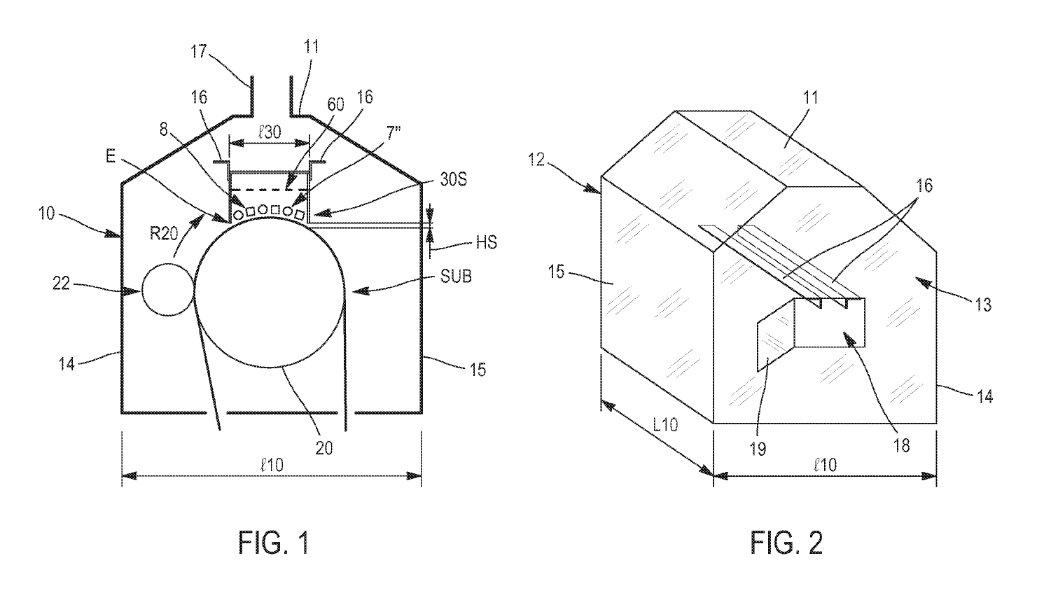

The height of each space E and S, namely the distance between each free edge 30E, 30S and the support, is typically between 0.5 and 2.5 millimeters, preferably between 0.8 and 1.2 millimeters. If this height is too small, the outlet of inert gas is insufficient and the lamination effect is not satisfactory. On the contrary, if this height is too big, there is not a sufficient overpressure value between the head and the rest of the chamber. In FIG. 1, the height HS is shown, the effective cross-section of the outlet S being defined by the product (HS*L30) of the height HS and the length L30.

The value of the height of each space E and S can be modified, by moving the head 30 with respect to the drum 20. This possibility is shown by the arrow T30 that underlines the translation movement of the head with respect to the support, as well as by the arrow R30 that underlines the movement of rotation of this head with respect to this support. As will be explained below, the modification of the relative position of the head and of the support allows the effective cross-section of the outlet to be modified.

The head is divided into two parts by a filter 60, hereinafter denoted as upper portion 40 and lower portion 50. In its upper portion 40, the head is provided with diffusion means, connected to a source of inert gas such as nitrogen, as will be described below. In the example illustrated these diffusion means are formed by a plurality of diffusers 42, of any suitable type.

In FIG. 4, D42 the distance of injection, namely the distance between the outlet of the diffusers 42 and the substrate SUB, should be noted. These diffusers, which have a plurality of diffusion holes, are formed regularly on the surface of the head. This filter, which is known per se, has, inter alia, the function of improving the homogeneity of the nitrogen sent to the lower portion 50 of the head.

The lower portion 50 of the head receives, first of all, members for injecting an active gaseous mixture. In the example illustrated, these members are injection tubes 7, 7′ and 7″, provided in a quantity of three. Alternatively, a different number of injection members can be provided and/or these injection members can be structurally different from a tube, namely they can be formed, for example, by a perforated bar.

The lower portion 50 of the head further receives three electrodes 8, 8′ and 8″, which are arranged alternately with respect to the tubes 7, 7′ and 7″, in the direction of rotation of the drum. In other words, the upstream tube 7 is placed between the lateral wall 34 and the upstream electrode 8, whereas the tubes 7′ and 7″ are placed between adjacent electrodes, namely 8, 8′ and 8′, 8″.

According to other alternatives that are not shown, the invention covers other mutual arrangement of tubes and electrodes. For example, two electrodes can be placed side by side, or a first tube can be positioned between an upstream electrode 8″ and the lateral wall 35. Two tubes can also be placed side by side, by being positioned between two electrodes or between a lateral wall and an electrode.

For example, the tubes are made out of metal, or out of plastic material, such as out of a polymer material, in particular out of PET. They are connected to a source, not shown, of an active gaseous mixture, in order to carry out a plasma treatment of the substrate SUB.

The structure of the tube 7 will now be described, with the other tubes 7′ and 7″ having the same structure. As shown in FIG. 5, the tube 7 is elongated and has a circular transverse cross-section. Its length L7, which is slightly less than that L30 of the head, is between for example 20 and 2,000 millimeters. Its outer diameter D7 is for example between 10 and 20 millimeters.

The tube 7 is pierced by two parallel rows 71 and 72 of injection orifices, made via any suitable method. These orifices extend along the length L71, which represents a substantial portion of the total length of these tubes.

In the example, there are two rows of holes, which are mutually offset. This allows the effects of the injection turbulence to be reduced, while improving the homogeneity of the final deposit. This prevents any undesired deposition of a parasite film on the electrodes themselves, which would reduce the rate of deposition on the substrate and would negatively affect the quality of this deposition.

The two ends of each tube are mounted on flanges 76, located near the front and rear walls, respectively. According to an advantageous embodiment, at least one of these ends is fastened onto a yoke 78, supported by a respective flange, that has the shape of a portion of a cylinder (see FIG. 7).

Consequently, this tube can be rotated about its main longitudinal axis, as shown by the arrow R7, which allows the angle of injection of the gaseous mixture in the direction of the substrate to be varied. This reduces the effects caused by the injection turbulence, as will be explained below.

Moreover, each tube is advantageously fastened onto the head removably, by snapping on or the equivalent. Consequently, a given tube can be replaced by another similar tube, in particular in case of a failure. The expression “different tubes” means that at least one of the following parameters varies from one tube to another:
Total size of the tube
Size of the holes
Positioning of these holes, in particular number of rows
Length L71 of the perforated zone.

Advantageously, each electrode has a smooth outer surface, which prevents the creation of turbulence in the zone in which the plasma is formed. This electrode is preferably made from a ceramic material, which allows an electrically conductive substrate to be treated. Alternatively, the electrodes can be made from any other suitable material, for example out of metal material.

The structure of the electrode 8 will now be described, with the electrodes 8′ and 8″ having the same structure. In reference to FIGS. 4 and 8, the electrode 8 is elongated and has a square-shaped transverse cross-section. Its length L8 is substantially equal to the length L7 of the tube 7, whereas its width 18 is similar to the diameter D7 of the tube 7, in particular between 10 and 20 millimeters.

The two ends of each electrode are fastened onto the flanges 76 (FIG. 4), near the ends of the tubes. Contrary to the tubes, these electrodes are not mounted on these flanges with a possibility of rotation. The electrodes 8 are connected to a source of very high voltage, not shown.

Moreover, each electrode is advantageously fastened onto the head removably, via any suitable means. Consequently, a given electrode can be replaced by another similar electrode, in particular in case of a failure. The expression “different electrodes” means that at least one of the following parameters varies from one tube to another:
Total size of the electrode
Material of the electrode
Shape of the electrode.

As also shown in FIG. 4, the electrodes 8 are connected to a shared source of nitrogen 90, via upstream lines 91. The nitrogen flows along these electrodes, then along downstream lines 92 that open into each diffuser 42.

Moreover, a sensor 94, of any suitable type, is suitable for measuring the oxygen concentration near the electrodes. As shown in FIG. 3, the sensor is positioned near the intake E. This sensor is connector to a control device 96, via a line 97, in such a way as to control the flow rate of nitrogen via an additional line 98, which opens into the source 90.

The smallest distance between the injection orifices 71, 72 and the substrate SUB is labeled d7, whereas d8 designates the smallest distance between each electrode 8 and the substrate. The distance d8 is for example between 500 and 2,500 micrometers, typically between 500 and 1,500 micrometers, in particular equal to 1,000 micrometers. Advantageously, the distance d7 is slightly greater than the distance d8. Thus, the head can be positioned with respect to the counter electrode 20, as explained above, without a risk of contact between the tubes 7 and this counter electrode.

Each tube is positioned substantially at an equal distance from the two electrodes, between which it is located. For example, the smallest distance d78 between a tube and an electrode is between 5 and 10 millimeters. If the distance d78 is too small, there is a risk of an electric arc being created. However, if d78 is too great, this can create a substantial dead volume, in which gaseous mixture can flow.

Various possibilities for implementing the method according to the invention, via the above facility, will now be described below.

In a previous phase, nitrogen is first introduced into the volume V via the diffusers 42. The substrate is not moved, until the oxygen concentration measured by the sensor 94 falls below a given threshold, for example equal to 20 ppm (parts per million). When the value of this concentration is suitable, the substrate is then moved via the support, while active gaseous mixture is injected via the tubes 7, and a discharge is generated by the electrodes 8.

This active gaseous mixture comprises a reactant gas suitable for being activated by the aforementioned electrical discharge. This reactant gas can comprise:
at least one dopant component, suitable for modifying the surface of the substrate for a later treatment, such as grafting or molecular functionalization. For example, this dopant can be:
an oxidizing gas, such as O₂, CO₂, N₂O or air
a reducing gas, such as H₂
a hydrocarbon, such as C₂H₂
a fluorinated gas, such as CHF₃.
at least one monomer component, suitable for creating a layer of deposit on the surface of the substrate, via polymerization with monomers present in the active gaseous mixture and/or on the surface of the substrate. This surface can have been previously subjected to molecular functionalization, as defined above, or undergo such functionalization afterwards. For example, this monomer can be:
an organosilicate, such as TEOS (TetraEthyl Orthosilicate)
a non-cyclical organosiloxane, such as HMDSO (Hexamethyl Di Siloxane)
a cyclical organosiloxane, such as OCTMS (Octamethyl Cyclo Tetra Siloxane)
an organosilane, such as OTES (Tri Ethoxy-N-Octylsilane).

The reactant gas can thus consist of the monomer, or the dopant, or a mixture of the monomer and the dopant. In the case of a mixture, the ratio between the volume fractions of the dopant and of the monomer is for example between 10 and 30.

The gaseous mixture can consist of the reactant gas, that is to say that it does not include a substantial fraction of another component. In particular, this gaseous mixture can consist of one or more dopants alone, in particular if the latter are suitable for such a use without any particular danger, such as N₂O or CO₂.

Alternatively, the gaseous mixture can comprise, besides the reactant gas, a carrier gas. The latter can be defined as a gas suitable for transporting the reactant gas, without modifying the nature of the latter, nor the nature of the substrate. In this case, the ratio between the volume fractions of the carrier gas and of the reactant gas is for example between 10 and 100.

A carrier gas, which is identical to the inert gas injected by the diffusers 42, can be chosen. In this case, this can typically be nitrogen.

According to an advantageous alternative, a carrier gas that is different than the inert gas can be chosen. In particular, a carrier gas that has improved plasma-generating properties with respect to nitrogen, such as a noble gas such as helium, can be chosen. Indeed, given that the quantity of carrier gas used is much less than the quantity of inert gas, this does not create unacceptable additional costs.

One of the uses at which the invention is aimed is plasma-assisted deposition. In this case, a reactant mixture consisting of at least one monomer, advantageously associated with at least one dopant and with a carrier gas, is used. Given that the dopant is injected at the same time as the monomer, this increases the quality and the homogeneity of the deposit, in particular because of the fact that the ratio between their concentrations is homogenous over the entire treated surface of the substrate.

Another one of the uses at which the invention is aimed is plasma-assisted grafting. In this case, a reactant mixture consisting of at least one dopant, associated if necessary with a carrier gas, is used. Given that the dopant is injected as close as possible to the substrate, it has very satisfactory homogeneity at the surface of said substrate. Moreover, any substantial loss of dopant is prevented since the risks of being carried away by the inert gas are reduced. Finally, if the dopant is acetylene, the undesired formation of powder on the electrodes is greatly reduced.

The inert gas, continuously injected by the diffusers 42, tends to press the gaseous mixture, which is injected by the tubes 7, against the substrate, namely as close as possible to the substrate. In order to guarantee a satisfactory pressing effect, the inner volume V of the head 30 is maintained at a slight overpressure with respect to the rest of the chamber 10.

As explained above, a suitable value for this overpressure is ensured by modifying, if necessary, the position of the head with respect to the support, according to the arrows T30 and/or R30. This tends to modify the height of the outlet S and consequently its effective cross-section, namely the cross-section of this outlet through which the gas evacuated outside of the volume V can flow. In addition or alternatively, action can also be taken on the value of the overall gaseous flow rate, which consists of the sum of the respective flow rates of the inert gas and of the active gaseous mixture.

Advantageously, the oxygen concentration is continuously measured by the sensor 94 is continuously measured during the plasma treatment. If this concentration exceeds the aforementioned threshold, the control device 90 increases the flow rate of nitrogen, in order to reduce this oxygen concentration. It should also be noted that the flow of nitrogen through the electrodes, via the lines 91, allows heat to be evacuated out of these electrodes.

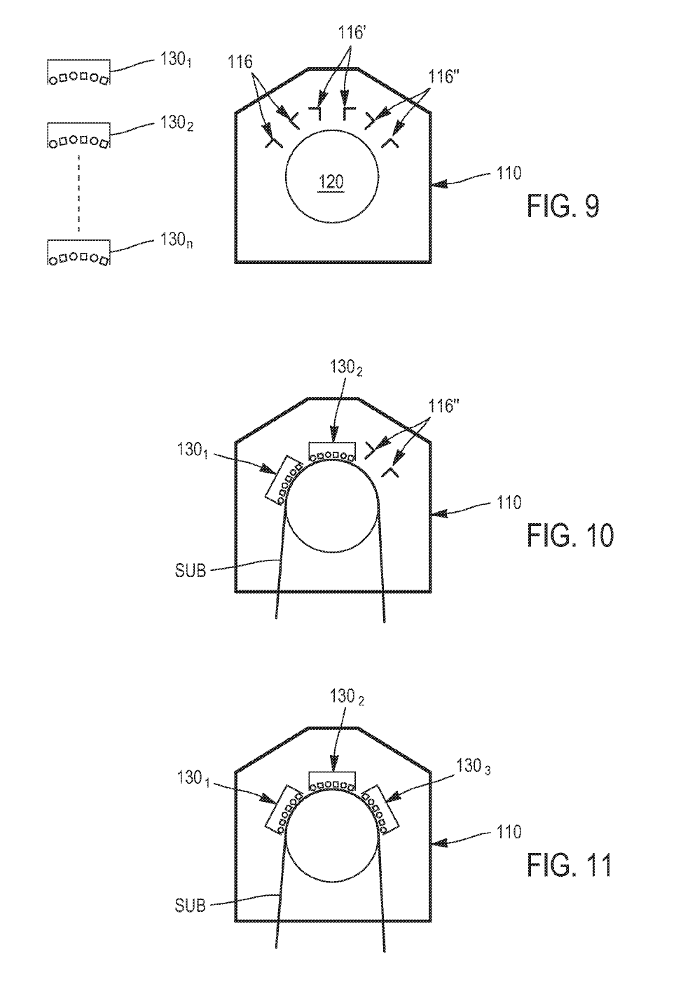

FIGS. 9 to 11 illustrate another advantageous embodiment of the invention. The mechanical elements in these FIGS. 9 to 11, which are similar to those of the embodiment of FIGS. 1 to 8, are assigned the same reference numbers increased by 100.

The chamber 110 is provided with a plurality of pairs of rails 116, 116′ and 116″, which extend side by side in the direction of movement of the substrate. In other words, there are, respectively, upstream rails 116, intermediate rails 116′ and downstream rails 116″. Access to these rails is allowed by windows and doors that are not shown, as described above. Moreover, the facility comprises a plurality of heads 130₁ to 130ₙ that can be identical or different, according to the definition given above.

According to a first possibility that is not shown, a single head can be positioned on a first pair of rails, in particular the intermediate pair 116′. A first type of treatment of the substrate can be carried out, as described above.

FIG. 10 shows another possibility in which two heads, for example the heads 130₁ and 130₂, are placed on respective rails, for example the rails 116 and 116′. If these heads are identical, a thicker deposit can be obtained without reducing the speed of the substrate. However, if these heads are different, namely that their tubes are supplied with different gaseous mixtures, the final deposit can include two layers of a different type.

According to an advantageous embodiment, it can be planned to carry out, in the first head 130₁, a preliminary plasma treatment aimed at at least partially eliminating the boundary layer of oxygen present on the substrate. For this purpose, the gaseous mixture injected into this first head is for example nitrogen, or a mixture of nitrogen and hydrogen. This guarantees a significant reduction in the quantity of gas consumed in the second head 130₂, for the inerting of its inner volume. Consequently, the total quantity of gas consumed for inerting the two heads 130₁ and 130₂ is reduced on the whole.

It should be noted that the liminal treatment, described in the paragraph above, can also be implemented if there is a single head, like the head 30 of FIGS. 1 to 8. In this case, the nitrogen, or the mixture of nitrogen and hydrogen, is injected in the upstream portion of the head, for example in the tube 7. Another gaseous mixture is then injected in the downstream portion of the head, for example in the tubes 7′ and 7″.

FIG. 11 shows yet another possibility in which three heads, for example the head 130₁, 130₂ and 130₃, are placed on the three pairs of rails. If these heads are identical, an even thicker deposit can be obtained without reducing the speed of the substrate. However, if two of these heads are identical but the third is different, the final deposit can include two layers of a different type, one of which is thicker than the other. Finally, if the three heads are different from each other, the final deposit can include three layers of a different type. It can also be planned to carry out, in the upstream head 130₁, a preliminary plasma treatment as described immediately above.

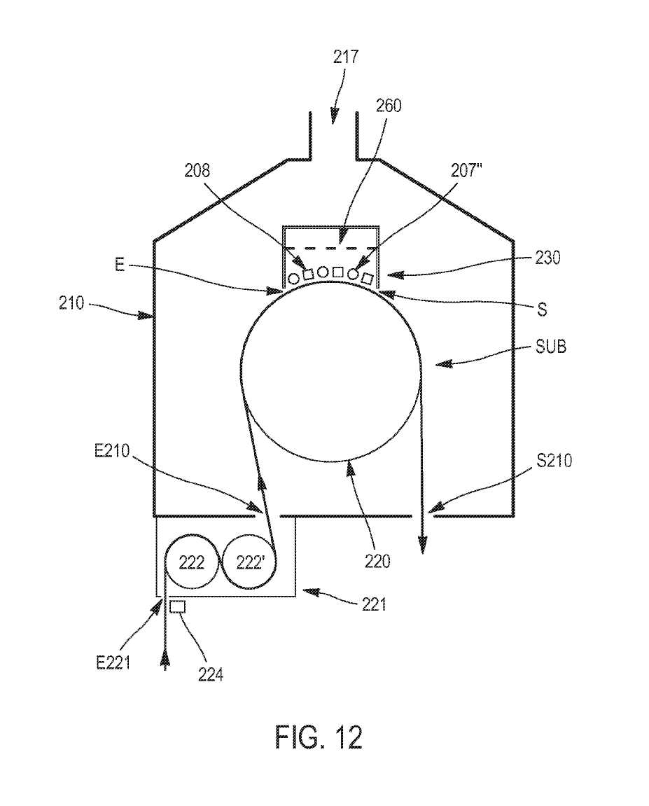

FIG. 12 illustrates an advantageous alternative of the invention. The mechanical elements of this FIG. 12, which are similar to those of the first embodiment of FIGS. 1 to 8, are assigned the same reference numbers increased by 200.

The chamber 210 is substantially closed and has three openings, namely that defined by the evacuation duct 217, as well as two slots. An upstream slot, or intake slot E210, ensures the passage of the substrate entering the inner volume of the chamber while a downstream slot, or outlet slot S210, ensures the passage of the substrate SUB exiting this inner volume.

The facility shown in this FIG. 12 further comprises an additional chamber, or preliminary chamber 221, which is located opposite the intake E210 and which receives two drive rollers 222 and 222′. This preliminary chamber 221 has its own intake slot E221, which allows the entry of the substrate. The outlet of this chamber 221 is the same as the intake E210 of the main chamber.

The preliminary chamber can be removably connected to the main chamber, via any suitable means. When on, the substrate is compressed between the rollers 222 and 222′, which allows the layer of air potentially present on the two opposite faces of the substrate to be substantially eliminated.

In the example illustrated, the facility comprises a single head 230. Alternatively, a plurality of heads is provided, like in the example of FIGS. 9 to 11. In this respect, providing a separate preliminary chamber 221 allows the use of the roller 22 of FIG. 1 to be avoided. Consequently, a more significant angular portion of the drum 220 is accessible, in particular for its association with a plurality of heads.

Advantageously, a suction device 224, placed near the intake E221, can be provided. When on, this device 224 can advantageously be activated, in such a way as to place the inner volume of the chamber 221 under a slight vacuum with respect to the inner volume of the chamber 210. For information, the difference in pressure between the chamber 210 and the chamber 221 is typically between 10 and 100 Pascal, namely between 20 and 50 Pascal. This allows elimination of the layer of air between the rollers 222 and 222′ to be improved.

In an alternative that is not shown, the suction device 224 can be actuated, while injecting an inerting gas, like nitrogen. Thus, the inner volume of the chamber 221 is not placed under vacuum. This prevents a significant quantity of air from entering the chamber 221, via the intake E221.

In an additional alternative, also not shown, a preliminary plasma treatment, such as that described in reference to FIG. 10, can be carried out in the chamber 221. This allows all or a portion of the oxygen boundary layer present on the substrate to be even more effectively eliminated.

### EXAMPLES

The invention is illustrated below by examples that do not, however, limit the scope thereof. These examples relate to two types of plasma treatments.

### Example 1

A facility such as that described in FIGS. 1 to 9 is used. The chamber has an overall volume of 1.15 m³, and the head has a volume of 0.02 m³. Three tubes, the diameter of which is 15 millimeters, three electrodes, the width of which is 15 millimeters, and eight identical diffusers are used.

The respective distances are the following:
d7=1.2 millimeters
18=1.0 millimeters
d78=5.0 millimeters
D42=120 millimeters
HS=0.8 millimeters.

A film of PET, the width of which is 1,200 millimeters and the thickness of which is 12 micrometers, is moved at a speed of 10 meters per minute.

The following are used:
TEOS (TetraEthyl OrthoSilicate) as the monomer
N₂O as the dopant
nitrogen as the inert gas
nitrogen as the carrier gas.

The monomer is vaporized at a temperature of close to 60° C. via a CEM (Controlled Evaporator Mixer) cell in a DBD (Dielectric Barrier Discharge) electrical discharge.
In a first implementation, according to the invention, the reactant gaseous mixture, consisting of the monomer, the dopant and the carrier gas, is injected in the tubes 7 at respective flow rates of 30 grams/hour, 3 liters/minute and 9 liters/minute. The inerting nitrogen is further injected at a flow rate of 300 liters/minute, via the diffusers 42.

This configuration lead to the formation of a deposit, the surface energy of which measured along the width has a satisfactory homogeneity. This deposit has a very high surface energy, measured at 105 mN/m according to the standard ASTM D-2578. The formation of a small quantity of powder, of a light color, on the electrodes and the walls of the tubes is noted.
Then, for comparison, a second implementation not according to the invention was carried out. For this purpose, the dopant N₂O was injected not in the tubes 7 with the monomer and the carrier gas, but in the diffusers 42 mixed with the inert gas. Moreover, all the other operational parameters remained unchanged.

This configuration led to the formation of a deposit having a much lower homogeneity. Indeed, the value for the surface energy varies, according to the width, between 48 and 58 mN/m. The formation of a much greater quantity of powder on the electrodes and the walls of the tubes is noted. Moreover, this powder is of a brown color.

### Example 2

A facility such as that described in FIGS. 1 to 9 is used. The chamber has an overall volume of 1.15 m³, and the head has a volume of 0.02 m³. Three tubes, the diameter of which is 15 millimeters, three electrodes, the width of which is 15 millimeters, and eight identical diffusers are used.

The respective distances are the following:
d7=1.2 millimeters
18=1.0 millimeters
d78=5.0 millimeters
D42=120 millimeters
HS=0.8 millimeters.

A film of PET, the width of which is 1,200 millimeters and the thickness of which is 12 micrometers, is moved at a speed of 100 meters per minute.

According to one of the embodiments of the invention, the reactant gaseous mixture comprises two dopants and two carrier gases. This overall gaseous mixture consists of two elementary mixtures, injected simultaneously. It should be noted that this overall gaseous mixture does not contain a monomer.

The first elementary mixture, injected in the three tubes, comprises 5% hydrogen as the dopant, as well as nitrogen as the carrier gas. The flow rate of this first elementary mixture is 2 liters/minute (overall flow rate for the 3 tubes).

The second elementary mixture, injected in the three tubes, comprises 1% acetylene as the dopant, as well as nitrogen as the carrier gas. The flow rate of this second elementary mixture is 2 liters/minute (overall flow rate for the 3 tubes).

Inerting nitrogen is further injected at a flow rate of 480 liters/minute.

The zones adjacent to the substrate and neighboring the electrodes 8, 8′ and 8″, respectively, are called upstream, intermediate and downstream discharge zone, respectively. 40% of the reactant gaseous mixture passes into the upstream discharge zone, 67% of this mixture passes into the intermediate discharge zone, and 86% of this mixture passes into the downstream discharge zone. In these conditions, only a very small fraction of the active gaseous mixture is evacuated out of the head, without having been put in contact with a discharge.

It is thus noted that the method of the invention allows the inerting power of the nitrogen to be improved and the stability of the plasma to be increased. The active species (H₂ and C₂H₂) remain confined to the discharge zones of the head.

This configuration allows a high surface energy, homogenous along the width and measured at 60 mN/m according to the standard ASTM D-2578, to be obtained on the film treated at 100 meters/minute.

Then, for comparison, a second implementation, which is not according to the invention, was carried out. For this purpose, the overall reactant mixture was injected not in the tubes 7 but in the diffusers 42 mixed with the inert gas (nitrogen).

This configuration lead to a worse-performing grafting efficiency. Indeed, it was not possible to obtain a high surface energy, homogenous along the width of the treated film and measured at 60 mN/m according to the standard ASTM D-2578, at a speed of movement of the PET film greater than 75 meters/minute.

1. A method for treating a surface of a moving substrate (SUB), in a facility comprising:
a chamber (10; 110; 210);
a support (20; 120; 220) for the substrate, received in said chamber;
a counter electrode (20; 120; 220);
at least one head (30; 130₁-130ₙ; 230), defining an inner volume (V) open towards the support, said head being provided:
with at least one electrode (8, 8′, 8″) suitable for cooperating with said counter electrode in order to create an electrical discharge;
diffusion means (42), for the diffusion of an inert gas towards said support; and
injection means (7, 7′, 7″), distinct from the diffusion means, for the injection of at least one active gaseous mixture towards said support, this active gaseous mixture comprising a reactant gas suitable for being activated by said electrical discharge;
the injection means being placed between the diffusion means and the support;
the head and the support defining at least one outlet (S) for the inert gas and/or the active gaseous mixture,
wherein in this method:
(i) both the inert gas and the active gaseous mixture are introduced towards said support, in such a way as to press the active gaseous mixture against said support;
(ii) the reactant gas is activated in said electrical discharge and the surface of said moving substrate is treated;
(iii) via said outlet (S), the gaseous atmosphere of the inner volume (V) is evacuated, said gaseous atmosphere comprising a fraction of the inert gas and of the active gaseous mixture;
(iv) the effective cross-section of the outlet (S) is adjusted and/or the total flow rate of the inert gas and of the active gaseous mixture is adjusted, in such a way that the difference in pressure between the inner volume (V) of each head and the inner volume of the chamber is greater than 10 Pascal,
with steps (i) to (iv) not necessarily being chronological.

2. The method according to claim 1, wherein the effective cross-section of the outlet is adjusted and/or the total flow rate of the inert gas and of the active gaseous mixture is adjusted, in such a way that the difference in pressure between the inner volume of each head and the inner volume of the chamber is greater than 20 Pascal, in particular greater than 50 Pascal.

3. The method according to claim 1, wherein the oxygen concentration in the inner volume of each head is measured and the effective cross-section of the outlet is adjusted and/or the total flow rate of the inert gas and of the active gaseous mixture is adjusted, if this measured concentration is outside of a predetermined range.

4. The method according to claim 1, wherein the active gaseous mixture comprises, besides the reactant gas, a carrier gas.

5. The method according to claim 4, wherein an inert gas of a first type, namely nitrogen, and a carrier gas of a different type, namely helium, are used.

6. The method according to claim 5, wherein a carrier gas that has improved plasma-generating properties with respect to nitrogen, such as a noble gas such as helium or argon, is chosen.

7. The method according to claim 1, wherein the reactant gas comprises at least one monomer and/or at least one dopant.

8. The method according to claim 1, wherein a first active gaseous mixture comprising hydrogen as the reactant gas is injected, into at least one upstream injection member, in order to eliminate at least a portion of the oxygen boundary layer present on the surface of the substrate, then a second active gaseous mixture different than the first active gaseous mixture is injected, into at least one downstream injection member, at the surface of the substrate freed from at least a portion of said layer of oxygen.

9. The method according to claim 8, wherein the or each upstream injection member is provided in an additional upstream chamber, distinct from the chamber, whereas the or each downstream injection member is provided in the chamber.

10. The method according to claim 8, wherein the or each upstream injection member is provided in a first head, or upstream head, of the chamber, whereas the or each downstream injection member is provided in a second head, or downstream head, of the chamber.

11. The method according to claim 8, wherein the or each upstream injection member, thus the or each downstream injection member, are provided in a single head.

12. The method according to claim 1, wherein the substrate passes into an auxiliary chamber (221), placed upstream of the chamber, and this substrate is pressed via at least one roller (222, 222′) received in this auxiliary chamber, in order to at least partially eliminate the layer of air present on the surface of the substrate.

13. The method according to claim 12, wherein the inner volume of this auxiliary chamber is placed under vacuum.

14. A facility for the implementation of a method according to claim 1, comprising:
a chamber (10; 110; 210);
a support (20; 120; 220) for the substrate (SUB), received in said chamber;
a counter electrode (20; 120; 220); at least one head (30; 130₁-130ₙ; 230) defining an inner volume (V) open towards the support, said head being provided:
with at least one electrode (8, 8′, 8″) suitable for cooperating with said counter electrode in order to create an electrical discharge;
diffusion means (42), for the diffusion of an inert gas towards said support; and
injection means (7, 7′, 7″) for the injection of at least one active gaseous mixture towards said support, this active gaseous mixture comprising a reactant gas suitable for being activated by said electrical discharge;
the injection means being placed between the diffusion means and the support,
the head and the support defining at least one outlet (S) for the inert gas and/or the active gaseous mixture this facility further comprising means for adjusting the effective cross-section of the outlet and/or means for adjusting the total flow rate of the inert gas and of the active gaseous mixture.

15. The facility according to claim 14, characterized in that it further comprises an auxiliary chamber (221), placed upstream of the chamber, said auxiliary chamber being provided with at least one press roller (222, 222′) suitable for at least partially eliminating the layer of air present on the surface of the substrate.
